(19) United States
(12) Patent Application Publication
(10) Pub. No.: US 2015/0380277 A1
(43) Pub. Date: Dec. 31, 2015

(54) UNDERFILL SHEET, UNDERFILL SHEET INTEGRATED WITH TAPE FOR GRINDING REAR SURFACE, UNDERFILL SHEET INTEGRATED WITH DICING TAPE, AND METHOD FOR MANUFACTURING SEMICONDUCTOR DEVICE

(71) Applicant: NITTO DENKO CORPORATION, Ibaraki-shi, Osaka (JP)

(72) Inventors: Kosuke Morita, Osaka (JP); Naohide Takamoto, Osaka (JP); Hiroyuki Hanazono, Osaka (JP); Akihiro Fukui, Osaka (JP)

(73) Assignee: NITTO DENKO CORPORATION, Ibaraki-shi, Osaka (JP)

(21) Appl. No.: 14/769,441

(22) PCT Filed: Feb. 7, 2014
(86) PCT No.: PCT/JP2014/052931

§ 371 Date: Aug. 20, 2015

(30) Foreign Application Priority Data
Feb. 21, 2013 (JP) 2013-032386

(51) Int. Cl. H01L 21/56; C08J 5/18; H01L 23/00; B32B 27/38; H01L 21/683; H01L 23/29

(52) U.S. Cl. CPC H01L 21/563; H01L 21/6836; H01L 23/293; H01L 24/83; B32B 27/38; C08J 5/18; H01L 2221/68327; H01L 2221/6834; H01L 2221/68377; H01L 2224/83191; H01L 2224/8385; B32B 2457/14; B32B 2264/102; C08J 2333/12; C08J 2333/08; C08J 2361/10; C08J 2433/12; C08J 2433/08; C08J 2433/20; C08J 2463/00

(57) ABSTRACT

An object of the present invention is to provide an underfill sheet that enables suitable filling of unevenness of a circuit surface of a semiconductor element, a suitable connection of a terminal of the semiconductor element and a terminal of an adherend, and suppression of outgas. The present invention relates to the underfill sheet having a viscosity of 1,000 Pa·s to 10,000 Pa·s at 150° C. and 0.05 to 0.20 rotations/min; and a minimum viscosity of 100 Pa·s or more at 100 to 200° C. and 0.3 to 0.7 rotations/min.

### TECHNICAL FIELD

The present invention relates to an underfill sheet, an underfill sheet integrated with a tape for grinding a rear surface, an underfill sheet integrated with a dicing tape, and a method for manufacturing a semiconductor device.

### BACKGROUND ART

In recent years, there has been a rapidly increasing demand for high density mounting due to a reduction in size and thickness of electronics. For this reason, a surface mounting semiconductor package that is suitable for high density mounting has become mainstream in place of a conventional pin inserting semiconductor package.

In order to protect the surface of a semiconductor element and to secure the connection reliability between the semiconductor element and the substrate, a space between the semiconductor element and the substrate is filled with liquid sealing resin after surface mounting. However, when the liquid sealing resin is used in the manufacture of a narrow-pitch semiconductor device, voids (air bubbles) may be generated. Accordingly, a technique has been proposed (Patent Document 1) in which a space between the semiconductor element and the substrate is filled by using a sheet-form sealing resin (underfill sheet).

### PRIOR ART DOCUMENT

### Patent Document

Patent Document 1: JP-4438973

### SUMMARY OF THE INVENTION

### Problems to be Solved by the Invention

Generally, in the process of using an underfill sheet, the circuit surface of a semiconductor element on which terminals (such as bumps) are provided and an underfill sheet are pasted to each other. Therefore, the underfill sheet is required to come into close contact by following the unevenness of the circuit surface. However, when the viscosity of the underfill sheet is high, the unevenness cannot be filled sufficiently, and voids may be generated. When a terminal of the semiconductor element and a terminal of an adherend are connected to each other, an underfill material between the terminals remains without being removed, which may result in a poor connection. On the other hand, when the viscosity of the underfill sheet is low, voids may be formed upon generation of outgas (gas that is generated during connecting or during thermal curing).

The present invention has been made in consideration of the above-described problems, and an object thereof is to provide an underfill sheet that can suitably fill unevenness, suitably connect a terminal of a semiconductor element and a terminal of an adherend, and suppress the generation of voids due to outgas. Another object of the invention is to provide an underfill sheet integrated with a tape for grinding a rear surface, an underfill sheet integrated with a dicing tape, and a method for manufacturing a semiconductor device.

### Means for Solving the Problems

The inventors of the present invention have found that the above-described problems can be solved by adopting the following configuration, and have completed the present invention.

That is, the present invention relates to an underfill sheet having a viscosity of 1,000 to 10,000 Pa·s at 150° C. and 0.05 to 0.20 rotations/min, and a minimum viscosity of 100 Pa·s or more at 100 to 200° C. and 0.3 to 0.7 rotations/min.

In the manufacturing process of a semiconductor device using an underfill sheet, a semiconductor element is generally fixed to an adherend with the underfill sheet interposed therebetween under a heating condition. The underfill sheet of the present invention has a viscosity of 1,000 to 10,000 Pa's at 150° C. and 0.05 to 0.20 rotations/min, so that the fluidity of the underfill sheet under heating condition falls within the optimum range, and this makes it possible to suitably fill the unevenness of the surface of the semiconductor element. Further, an underfill material between terminals can be suitably removed, so that a terminal of the semiconductor element and a terminal of the adherend can be suitably connected to each other.

The underfill sheet of the present invention has a minimum viscosity of 100 Pa·s or more at 100 to 200° C. and 0.3 to 0.7 rotations/min, so that the generation of voids due to outgas can be suppressed.

The underfill sheet of the present invention preferably contains 15 to 70% by weight of a silica filler having an average particle size of 0.01 to 10 μm and 2 to 30% by weight of an acrylic resin. This can suitably achieve the above-described viscosity.

In the underfill sheet of the present invention, a storage modulus E′ [MPa] and a thermal expansion coefficient α [ppm/K] after thermally curing at 175° C. for 1 hour preferably satisfy the following Formula (1) at 25° C.

E′×α<250,000 [Pa/K] (1)

When the storage modulus E′ [MPa] and the thermal expansion coefficient α [ppm/K] of the underfill sheet after thermal curing satisfy Formula (1) above, a difference of the thermal response behaviors between the semiconductor element and the adherend can be reduced, and a semiconductor device can be obtained which has suppressed joint breakage and high connection reliability. In Formula (1) above, the storage modulus E′ and the thermal expansion coefficient α have an inversely proportional relationship. When the storage modulus E′ increases, the rigidity of the underfill sheet itself improves, so that stress can be absorbed or dispersed. At this time, the thermal expansion coefficient α decreases, and the thermal expansion behavior of the underfill sheet itself is suppressed. Therefore, mechanical damage to the adjacent members (i.e., semiconductor element and adherend) can be reduced. On the other hand, when the storage modulus E′ decreases, the flexibility of the underfill sheet itself improves, and the thermal response behavior of the adjacent members, especially the adherend, can be absorbed. At this time, the thermal expansion coefficient α increases, the influence to the semiconductor element is suppressed due to the decrease of the storage modulus E′, and the stress is relaxed as a whole while the thermal response behavior of the underfill sheet synchronizes with the thermal response behavior of the adherend. The relaxation of stress can be optimized among the semiconductor element, the adherend, and the underfill sheet, so that the breakage of the connection members (bumps) can be also suppressed. As a result, the connection reliability of the semiconductor device can be improved. The measurement methods of the storage modulus E′ and the thermal expansion coefficient α are in accordance with the description in the Examples.

The storage modulus E′ is preferably 100 to 10,000 [MPa], and the thermal expansion coefficient α is preferably 10 to 200 [ppm/K]. When each of the storage modulus E′ and the thermal expansion coefficient α falls within the above range, the stress of the entire system can be effectively relaxed.

The storage modulus E′ [MPa] and the thermal expansion coefficient α [ppm/K] preferably satisfy the following Formula (2).

10,000<E′×α<250,000 [Pa/K] (2)

When the storage modulus E′ and the thermal expansion coefficient α satisfy Formula (2) above, the relaxation of stress can be easily optimized among the semiconductor element, the adherend, and the underfill sheet.

The underfill sheet of the present invention preferably contains a thermosetting resin. The thermosetting resin preferably contains an epoxy resin and a phenol resin. This makes it possible to suitably achieve the above-described viscosity, and to easily allow the underfill sheet to satisfy Formula (1) above.

The present invention also relates to an underfill sheet integrated with a tape for grinding a rear surface comprising the tape for grinding the rear surface and the underfill sheet laminated on the tape for grinding the rear surface. The tape for grinding the rear surface and the underfill sheet are integrally used to improve manufacturing efficiency.

The present invention also relates to an underfill sheet integrated with a dicing tape comprising a dicing tape and the underfill sheet laminated on the dicing tape. The tape for grinding the rear surface and the underfill sheet are integrally used to improve manufacturing efficiency.

The present invention also relates to a method for manufacturing a semiconductor device comprising a step of fixing a semiconductor element to an adherend with the underfill sheet interposed therebetween.

### BRIEF DESCRIPTION OF THE DRAWINGS

FIG. 1 is a schematic cross sectional view of an underfill sheet integrated with a tape for grinding a rear surface.

FIG. 2A is a view showing one step of a method for manufacturing a semiconductor device using the underfill sheet integrated with the tape for grinding the rear surface.

FIG. 2B is a view showing one step of the method for manufacturing the semiconductor device using the underfill sheet integrated with the tape for grinding the rear surface.

FIG. 2C is a view showing one step of the method for manufacturing the semiconductor device using the underfill sheet integrated with the tape for grinding the rear surface.

FIG. 2D is a view showing one step of the method for manufacturing the semiconductor device using the underfill sheet integrated with the tape for grinding the rear surface.

FIG. 2E is a view showing one step of the method for manufacturing the semiconductor device using the underfill sheet integrated with the tape for grinding the rear surface.

FIG. 2F is a view showing one step of the method for manufacturing the semiconductor device using the underfill sheet integrated with the tape for grinding the rear surface.

FIG. 2G is a view showing one step of the method for manufacturing the semiconductor device using the underfill sheet integrated with the tape for grinding the rear surface.

FIG. 3 is a schematic cross sectional view of an underfill sheet integrated with a dicing tape.

FIG. 4A is a view showing one step of a method for manufacturing a semiconductor device using the underfill sheet integrated with the dicing tape.

FIG. 4B is a view showing one step of the method for manufacturing the semiconductor device using the underfill sheet integrated with the dicing tape.

FIG. 4C is a view showing one step of the method for manufacturing the semiconductor device using the underfill sheet integrated with the dicing tape.

FIG. 4D is a view showing one step of the method for manufacturing the semiconductor device using the underfill sheet integrated with the dicing tape.

### MODE FOR CARRYING OUT THE INVENTION

[Underfill Sheet]

The underfill sheet of the present invention has a viscosity of 1,000 Pa·s or more, and preferably 2,000 Pa·s or more at 150° C. and 0.05 to 0.20 rotations/min. The viscosity of 1,000 Pa·s or more can prevent contamination of a pressure apparatus caused by the resin that leaks out when the pressure is applied.

The underfill sheet of the present invention has a viscosity of 10,000 Pa·s or less, and preferably 8,000 Pa·s or less at 150° C. and 0.05 to 0.20 rotations/min. The viscosity of 10,000 Pa·s or less makes the fluidity of the underfill sheet under heating condition fall within the optimum range, and the underfill sheet can suitably fill the unevenness of the semiconductor element surface. Further, an underfill material between terminals can be suitably removed, so that a terminal of the semiconductor element and a terminal of the adherend can be suitably connected to each other.

The viscosity at 150° C. and 0.05 to 0.20 rotations/min can be controlled by the particle size of the silica filler, the content of the silica filler, the content of the acrylic resin, the molecular weight of the acrylic resin, the content of the thermosetting resin, etc.

For example, the viscosity at 150° C. and 0.05 to 0.20 rotations/min can be increased by decreasing the particle size of the silica filler, increasing the content of the silica filler, increasing the content of the acrylic resin, increasing the molecular weight of the acrylic resin, or decreasing the content of the thermosetting resin.

The underfill sheet of the present invention has a minimum viscosity of 100 Pa·s or more, and preferably 500 Pa·s or more at 100 to 200° C. and 0.3 to 0.7 rotations/min. The minimum viscosity of 100 Pa·s or more can suppress the generation of voids due to outgas.

The underfill sheet of the present invention has a minimum viscosity of 10,000 Pa·s or less, and preferably 8,000 Pa·s or less at 100 to 200° C. and 0.3 to 0.7 rotations/min. If the minimum viscosity is 10,000 Pa's or less, the fluidity of the underfill sheet under the heating condition falls within the optimum range, and the underfill sheet can suitably fill the unevenness of the semiconductor element surface. Further, an underfill material between terminals can be suitably removed, so that a terminal of the semiconductor element and a terminal of the adherend can be suitably connected to each other.

The minimum viscosity at 100 to 200° C. and 0.3 to 0.7 rotations/min can be controlled by the particle size of the silica filler, the content of the silica filler, the content of the acrylic resin, the molecular weight of the acrylic resin, the content of the thermosetting resin, etc.

For example, the minimum viscosity at 100 to 200° C. and 0.3 to 0.7 rotations/min can be increased by decreasing the particle size of the silica filler, increasing the content of the silica filler, increasing the content of the acrylic resin, increasing the molecular weight of the acrylic resin, or decreasing the content of the thermosetting resin.

The viscosity at 150° C. and 0.05 to 0.20 rotations/min and the minimum viscosity at 100 to 200° C. and 0.3 to 0.7 rotations/min can be measured by using a rheometer. Specifically, they can be measured with the method described in the Examples.

In the underfill sheet of the present invention, a storage modulus E′ [MPa] and a thermal expansion coefficient α [ppm/K] after thermally curing at 175° C. for 1 hour preferably satisfy the following Formula (1) at 25° C.

E′×α<250,000 [Pa/K] (1)

When Formula (1) above is satisfied, a difference of the thermal response behaviors between the semiconductor element and the adherend can be reduced, and a semiconductor device can be obtained which has suppressed joint breakage and high connection reliability. The relaxation of stress can be optimized among the semiconductor element, the adherend, and the underfill sheet, so that the breakage of the connection members can be also suppressed, and the connection reliability of the semiconductor device can be improved.

The storage modulus E′ is preferably 100 to 10,000 [MPa], and the thermal expansion coefficient α is preferably 10 to 200 [ppm/K]. When each of the storage modulus E′ and the thermal expansion coefficient α falls within this range, the stress of the entire semiconductor device system can be effectively relaxed.

The storage modulus E′ [MPa] and the thermal expansion coefficient α [ppm/K] preferably satisfy the following Formula (2).

10,000<E′×α<250,000 [Pa/K] (2)

When the storage modulus E′ and the thermal expansion coefficient α of the underfill sheet after thermal curing satisfy Formula (2) above, the relaxation of stress can be easily optimized among the semiconductor element, the adherend, and the underfill sheet.

A glass transition temperature (T_{g}) after the underfill sheet is thermally cured at 175° C. for 1 hour is preferably 100 to 180° C., and more preferably 130 to 170° C. When the glass transition temperature of the underfill sheet after thermal curing falls within this range, a rapid change of physical properties can be suppressed in the temperature range of a thermal cycle reliability test, and a further improvement in reliability can be expected.

The water absorption of the underfill sheet before thermal curing under conditions of a temperature of 23° C. and a humidity of 70% is preferably 1% by weight or less, and more preferably 0.5% by weight or less. When the underfill sheet has the water absorption as described above, the absorption of moisture by the underfill sheet can be suppressed, and the generation of voids can be effectively suppressed when the semiconductor element is mounted. The smaller the lower limit of the water absorption, the better it is. The water absorption is preferably substantially 0% by weight, and more preferably 0% by weight.

An acrylic resin is preferably used as a constituting material of the underfill sheet from the points that it has less ionic impurities, high heat resistance, and can secure the reliability of the semiconductor element.

The acrylic resin is not particularly limited, and examples thereof include polymers having as a component one or more of esters of acrylic acids or methacrylic acids which have a linear or branched alkyl group having 30 or less of carbon atoms, especially 4 to 18 carbon atoms. Examples of the alkyl group include a methyl group, an ethyl group, a propyl group, an isopropyl group, an n-butyl group, a t-butyl group, an isobutyl group, an amyl group, an isoamyl group, a hexyl group, a heptyl group, a cyclohexyl group, a 2-ethylhexyl group, an octyl group, an isooctyl group, a nonyl group, an isononyl group, a decyl group, an isodecyl group, an undecyl group, a lauryl group, a tridecyl group, a tetradecyl group, a stearyl group, an octadecyl group, and a dodecyl group.

Other monomers for forming the polymer are not particularly limited, and examples thereof include cyano group-containing momomers such as acrylonitrile, carboxyl group-containing monomers such as acrylic acid, methacrylic acid, carboxyethyl acrylate, carboxypentyl acrylate, itaconic acid, maleic acid, fumaric acid, and crotonic acid, acid anhydride monomers such as maleic anhydride and itaconic anhydride, hydroxyl group-containing monomers such as 2-hydroxyethyl (meth) acrylate, 2-hydroxypropyl (meth) acrylate, 4-hydroxybutyl (meth) acrylate, 6-hydroxyhexyl (meth) acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate, sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth)acrylate and (meth)acryloyloxynaphthalenesulfonic acid, and phosphoric acid group-containing monomers such as 2-hydroxyethylacryloyl phosphate.

The content of the acrylic resin in the underfill sheet is preferably 2% by weight or more, and more preferably 5% by weight or more. If the content is 2% by weight or more, the minimum viscosity can be suitably adjusted. The content of the acrylic resin in the underfill sheet is preferably 30% by weight or less, and more preferably 25% by weight or less. If the content is 30% by weight or less, the viscosity at 150° C. can easily fall within the above-described range, and the underfill sheet can suitably fill the unevenness of the semiconductor element surface. An underfill material between terminals can be suitably removed, so that a terminal of the semiconductor element and a terminal of the adherend can be suitably connected to each other.

A thermosetting resin is preferably used as a constituting material of the underfill sheet.

Examples of the thermosetting resin include a phenol resin, an amino resin, an unsaturated polyester resin, an epoxy resin, a polyurethane resin, a silicone resin, and a thermosetting polyimide resin. These resins may be used either alone or in a combination of two or more thereof. Especially, an epoxy resin is preferable due to the points that it has a small amount of ionic impurities and the like that corrode the semiconductor element, the leakage of adhesive of the underfill sheet can be suppressed at the cut surface of dicing, and the reattaching (blocking) of the cut surfaces can be suppressed. A phenol resin is preferable as a curing agent for the epoxy resin.

The epoxy resin is not particularly limited as long as it is generally used as an adhesive composition, and for example a difunctional epoxy resin or a polyfunctional epoxy resin such as a bisphenol A type, a bisphenol F type, a bisphenol S type, a brominated bisphenol A type, a hydrogenated bisphenol A type, a bisphenol AF type, a biphenyl type, a naphthalene type, a fluorene type, a phenol novolak type, an orthocresol novolak type, a trishydroxyphenyl methane type, or a tetraphenylol ethane type, or an epoxy resin such as a hydantoin type, a trisglycidyi isocyanurate type, or a glycidyl amine type is used. They can be used alone, or in a combination of two or more thereof. Among these epoxy resins, a novolak type epoxy resin, a biphenyl type epoxy resin, a trishydroxyphenyl methane type resin, or a tetraphenylol ethane type epoxy resin is especially preferable. This is because the aforementioned resins have a high reactivity with a phenol resin as a curing agent, and are excellent in heat resistance and so on.

Further, the phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, resole type phenol resins, and polyoxystyrenes such as polyparaoxystyrene. They can be used alone, or in a combination of two or more thereof. Among these phenol resins, a phenol novolak resin, and a phenol aralkyl resin are especially preferable. This is because the connection reliability of a semiconductor device can be improved.

The compounding ratio of the phenol resin to the epoxy resin is preferably set so that the hydroxy group in the phenol resin is 0.5 to 2.0 equivalents per one equivalent of the epoxy group in the epoxy resin component. The hydroxy group in the phenol resin is more preferably 0.8 to 1.2 equivalents. If it is outside of this range, the curing reaction does not proceed sufficiently, and the characteristics of the underfill sheet can easily deteriorate.

The content of the thermosetting resin in the underfill sheet is preferably 10% by weight or more, and more preferably 20% by weight or more. If the content is 10% by weight or more, the thermal characteristics after curing improve, and the reliability is easily maintained. The content of the thermosetting resin in the underfill sheet is preferably 80% by weight or less, and more preferably 70% by weight or less. If the content is 80% by weight or less, the stress is easily relaxed, and the reliability is easily maintained.

A thermal-curing promoting catalyst for the epoxy resin and the phenol resin is not particularly limited, and can be appropriately selected from known thermal-curing promoting catalysts and used. The thermal-curing promoting catalyst can be used alone, or in a combination of two or more kinds. As the thermal-curing promoting catalyst, for example, an amine-based curing accelerator, a phosphorus-based curing accelerator, an imidazole-based curing accelerator, a boron-based curing accelerator, or phosphorus-boron-based curing accelerator can be used.

The content of the thermal-curing promoting catalyst is preferably 0.1 parts by weight or more to the total content 100 parts by weight of the epoxy resin and the phenol resin. If the content is 0.1 parts by weight or more, the curing time by the heat treatment becomes small, and the productivity can be improved. The content of the thermal-curing promoting catalyst is preferably 5 parts by weight or less. If the content is 5 parts by weight or less, the preservability of the thermosetting resin can be improved.

A flux may be added to the underfill sheet in order to remove the oxide film on the solder bump surface to ease mounting of the semiconductor element. The flux is not particularly limited, a previously known compound having an a flux action can be used, and examples thereof include diphenolic acid, adipic acid, acetylsalicylic acid, benzoic acid, benzilic acid, azelaic acid, benzylbenzoic acid, malonic acid, 2,2-bis(hydroxvmethyl)propionic acid, salicylic acid, o-methoxybenzoic acid, m-hydroxybenzoic acid, succinic acid, 2,6-dimethoxymethyl paracresol, hydrazide benzoate, carbohydrazide, dihydrazide malonate, dihydrazide succinate, dihydrazide glutarate, hydrazide salicylate, dihydrazide iminodiacetate, dihydrazide itaconate, trihydrazide citrate, thiocarbohydrazide, benzophenone hydrazone, 4,4′-oxybisbenzenesulfonyl hydrazide, and dihydrazide adipate. The amount of the flux added may be any amount as long as the flux action described above can be exhibited, and it is normally about 0.1 to 20 parts by weight to 100 parts by weight of the resin components (resin components such as an acrylic resin and a thermosetting resin) contained in the underfill sheet.

The underfill sheet may be colored as necessary. The color that is given by coloring of the underfill sheet is not especially limited; however, black, blue, red, green, etc. are preferable. A coloring agent can be used that is appropriately selected from known coloring agents such as a pigment and a dye.

When the underfill sheet is cross-linked to a certain extent in advance, it is preferable to add a multifunctional compound that reacts with a functional group, etc., at the ends of the polymer molecular chain as a cross-linking agent in production. This makes it possible to improve the adhesion characteristics under high temperatures and to improve the heat resistance.

Especially, a polyisocyanate compound is more preferable as the cross-linking agent such as tolylene diisocyanate, diphenylmethane diisocyanate, p-phenylene diisocyanate, 1,5-naphthalene diisocyanate, and an adduct of polyhydric alcohol and diisocyanate. The content of the cross-linking agent can be appropriately set, and for example, is preferably 1 part by weight or more, and more preferably 5 parts by weight or more to 100 parts by weight of the resin components (resin components such as an acrylic resin and a thermosetting resin). If the content is 1 part by weight or more, the minimum viscosity can be suitably adjusted. The content of the cross-linking agent is preferably 50 parts by weight or less, and more preferably 20 parts by weight or less. If the content is 50% by weight or less, the heat resistance can be improved while maintaining the fluidity.

A silica filler having an average particle size of 0.01 to 10 μm is preferably compounded in the underfill sheet. This makes it possible to adjust the range of the viscosity and the storage modulus. In addition, the electric conductivity and the thermal conductivity can be improved. The silica filler is not especially limited, but fused silica can be suitably used.

The silica filler has an average particle size of preferably 0.01 μm or more, and more preferably 0.05 μm or more. If the average particle size is 0.01 μm or more, the influence of the surface area of the filler on the sheet flexibility can be suppressed. The silica filler has an average particle size of preferably 10 μm or less, and more preferably 1 μm or less. If the average particle size is 10 μm or less, the silica filler can effectively fill the gap between the chip and the substrate.

The average particle size is a value obtained with an optical particle size analyzer (name of analyzer: LA-910; manufactured by HORIBA, Ltd.).

The content of the silica filler in the underfill sheet is preferably 15% by weight or more, and more preferably 40% by weight or more. If the content is 15% by weight or more, the viscosity of the resin at high temperatures can be easily maintained. The content of the silica filler in the underfill sheet is preferably 70% by weight or less. If the content is 70% by weight or less, the fluidity of the thermosetting resin at 150° C. can be maintained, and the property of filling the unevenness can be enhanced.

Other additives can be appropriately compounded in the underfill sheet as necessary. Examples of the other additives include a flame retardant, a silane coupling agent, and an ion trapping agent. Examples of the flame retardant include antimony trioxide, antimony pentoxide, and a brominated epoxy resin. These may be used either alone or in a combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds may be used either alone or in a combination of two or more thereof. Examples of the ion trapping agent include hydrotalcites and bismuth hydroxide. These may be used either alone or in a combination of two or more thereof.

For example, the underfill sheet can be produced as follows. First, each of the components described above that are constituent materials of the underfill sheet is compounded, and is dissolved or dispersed in a solvent (for example, methylethylketone or ethylacetate) to prepare a coating liquid. Next, the prepared coating liquid is applied onto a base separator to form a coating film having a prescribed thickness. Then, the coating film is dried under a prescribed condition to form an underfill sheet.

The thickness of the underfill sheet may be appropriately set in consideration of the gap between the semiconductor element and the adherend or the height of the connection members. The thickness is preferably 10 to 100 μm.

The underfill sheet is preferably protected by a separator. The separator has a function as a protecting material to protect the underfill sheet before use. The separator is peeled off when the semiconductor element is pasted onto the underfill sheet. Polyethylene terephthalate (PET), polyethylene, polypropylene, a plastic film, and a paper sheet with a surface which is coated with a peeling agent such as a fluorine peeling agent or a long-chain alkylacrylate peeling agent can be also used as a separator.

A semiconductor device can be manufactured with a normal method using the underfill sheet of the present invention. Specifically, the semiconductor element is fixed to the adherend with the underfill sheet interposed therebetween under the heating condition to manufacture a semiconductor device.

The heating condition is not especially limited; however, it is preferably 200 to 300° C. The underfill sheet of the present invention has the above-described viscosity characteristics, so that the fluidity falls within the optimum range under the heating condition, the underfill sheet can suitably fill the unevenness of the semiconductor element surface, and the terminals can be suitably connected to each other. Further, the generation of voids due to outgas can be suppressed.

Examples of the semiconductor element include a semiconductor wafer and a semiconductor chip. Examples of the adherend include a wired circuit board, a flexible board, an interposer, a semiconductor wafer, and a semiconductor chip.

[Underfill Sheet Integrated with Tape for Grinding Rear Surface]

The underfill sheet integrated with a tape for grinding a rear surface of the present invention includes the tape for grinding the rear surface and the underfill sheet.

FIG. 1 is a schematic cross sectional view of an underfill sheet integrated with a tape for grinding a rear surface 10. As shown in FIG. 1, the underfill sheet integrated with the tape for grinding the rear surface 10 includes a tape 1 for grinding the rear surface and an underfill sheet 2 that is laminated on the tape for grinding the rear surface. As shown in FIG. 1, the underfill sheet 2 may not be laminated on the entire surface of the tape 1 for grinding rear surface, and it is satisfactory if the underfill sheet 2 is provided to a size that is sufficient for pasting with a semiconductor wafer 3 (refer to Fig. A).

(Tape for Grinding Rear Surface)

The tape 1 for grinding the rear surface includes a base 1a and a pressure-sensitive adhesive layer 1b that is laminated on the base 1a. The underfill sheet 2 is laminated on the pressure-sensitive adhesive layer 1b.

The base 1a becomes a base material for strength of the underfill sheet integrated with a tape for grinding the rear surface 10. Examples include polyolefins such as low-density polyethylene, linear polyethylene, medium-density polyethylene, high-density polyethylene, very low-density polyethylene, random copolymerized polypropylene, block copolymerized polypropylene, homo polypropylene, polybutene and polymethylpentene, an ethylene-vinyl acetate copolymer, an ionomer resin, an ethylene-(meth)acrylic acid copolymer, an ethylene-(meth)acrylate (random, alternating) copolymer, an ethylene-butene copolymer, an ethylene-hexene copolymer, polyurethane, polyesters such as polyethylene terephthalate and polyethylene naphthalate, polycarbonate, polyimide, polyether ether ketone, polyimide, polyetherimide, polyamide, total aromatic polyamide, polyphenyl sulfide, alamid (paper), glass, glass cloth, a fluororesin, polyvinyl chloride, polyvinylidene chloride, a cellulose-based resin, a silicone resin, a metal (foil), and papers such as glassine paper. When the pressure-sensitive adhesive layer 1b is of an ultraviolet-ray curing type, the base 1a is preferably permeable to ultraviolet rays.

A common surface treatment can be performed on the surface of the base 1a.

For the base 1a, the same material or different materials can be appropriately selected and used, and one obtained by blending several materials can be used as necessary. The base 1a can have provided thereon a vapor-deposited layer of an electrically conductive substance made of a metal, an alloy, an oxide thereof, or the like having a thickness of about 30 to 500 Å for imparting an antistatic property. The base 1a may be a single layer or a multiple layer having two or more layers.

The thickness of the base 1a is not particularly limited, and can be appropriately determined, but is generally about 5 to 200 μm, and is preferably 35 to 120 μm.

The base 1a may contain various kinds of additives (e.g. colorant, filler, plasticizer, antiaging agent, antioxidant, surfactant, flame retardant, etc.) within the bounds of not impairing the effect of the present invention.

A pressure-sensitive adhesive used for forming the pressure-sensitive adhesive layer 1b is not particularly limited as long as it can tightly hold a semiconductor wafer or a semiconductor chip through the underfill sheet at the time of dicing, and provide control so that the semiconductor chip with the underfill sheet can be peeled off during pickup. For example, a general pressure-sensitive adhesive such as an acryl-based pressure-sensitive adhesive or a rubber-based pressure-sensitive adhesive can be used. As the pressure-sensitive adhesive, an acryl-based pressure-sensitive adhesive having an acryl-based polymer as a base polymer is preferable from the viewpoint of ease of cleaning of an electronic component sensitive to contamination, such as a semiconductor wafer or glass, using ultrapure water or an organic solvent such as an alcohol.

Examples of the acryl-based polymer include those using an acrylate as a main monomer component. Examples of the acrylate include one or more of (meth)acrylic acid alkyl esters (for example, linear or branched alkyl esters with the alkyl group having 1 to 30, particularly 4 to 18 carbon atoms, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nony ester, decyl ester, isodecyl ester, undecyl ester, dodecyl ester, tridecyl ester, tetradecyl ester, hexadecyl ester, octadecyl ester and eicosyl ester) and (meth)acrylic acid cycloalkyl esters (for example, cyclopentyl ester and cyclohexyl ester, etc.). The (meth)acrylic acid ester refers to an acrylic acid ester and/or a methacrylic acid ester, and (meth) has the same meaning throughout the present invention.

The acryl-based polymer may contain a unit corresponding to any other monomer component capable of being copolymerized with the (meth) acrylic acid alkyl ester or cycloalkyl ester as necessary for the purpose of modifying cohesive strength, heat resistance, and so on. Examples of the monomer component include carboxyl group-containing monomers such as acrylic acid, methacrylic acid, carboxyethyl (meth) acrylate, carboxypentyl (meth) acrylate, itaconic acid, maleic acid, fumaric acid and crotonic acid; acid anhydride monomers such as maleic anhydride and itaconic anhydride; hydroxyl group-containing monomers such as 2-hydroxyethyl (meth)acrylate, 2-hydroxypropyl (meth) acrylate, 4-hydroxybutyl (meth) acrylate, 6-hydroxyhexyl (meth) acrylate, 8-hydroxyoctyl (meth) acrylate, 10-hydroxydecyl (meth)acrylate, 12-hydroxylauryl (meth)acrylate, and (4-hydroxymethylcyclohexyl)-methyl (meth) acrylate; sulfonic acid group-containing monomers such as styrenesulfonic acid, allylsulfonic acid, 2-(meth)acrylamide-2-methylpropanesulfonic acid, (meth) acrylamidepropanesulfonic acid, sulfopropyl (meth) acrylate, and (meth) acryloyloxynaphthalenesulfonic acid; phosphoric acid group-containing monomers such as 2-hydroxyethylacryloyl phosphate; and acrylamide and acrylonitrile. One or more of these monomers capable of being copolymerized can be used. The used amount of the monomer component capable of copolymerization is preferably 40% by weight or less based on total monomer components.

Further, the acryl-based polymer may contain a polyfunctional monomer or the like as a monomer component for copolymerization as necessary for the purpose of cross-linking. Examples of the polyfunctional monomer include hexanediol di(meth)acrylate, (poly)ethylene glycol di(meth)acrylate, (poly)propylene glycol di (meth) acrylate, neopentylglycol di (meth) acrylate, pentaerythrithol di(meth)acrylate, trimethylolpropane tri(meth)acrylate, pentaerythrithol tri(meth)acrylate, dipentaerythrithol hexa(meth)acrylate, epoxy (meth) acrylate, polyester (meth)acrylate, and urethane (meth)acrylate. One or more of these polyfunctional monomers can be used. The used amount of the polyfunctional monomer is preferably 30% by weight or less based on total monomer components from the viewpoint of an adhesion property.

The acryl-based polymer is obtained by subjecting a single monomer or monomer mixture of two or more kinds of monomers to polymerization. Polymerization can be carried out by any method such as solution polymerization, emulsion polymerization, bulk polymerization, or suspension polymerization. The content of low-molecular weight substances is preferably low from the viewpoint of prevention of contamination of a clean adherend. In this respect, the number average molecular weight of the acryl-based polymer is preferably 300,000 or more, further preferably about 400,000 to 3,000,000.

For the pressure-sensitive adhesive, an external cross-linker can also be appropriately employed for increasing the number average molecular weight of an acryl-based polymer or the like as a base polymer. Specific examples of the external cross-linking methods include a method in which a so called cross-linker such as a polyisocyanate compound, an epoxy compound, an aziridine compound, or a melamine-based cross-linker is added and reacted. When an external cross-linker is used, the used amount thereof is appropriately determined according to a balance with a base polymer to be cross-linked, and further a use application as a pressure-sensitive adhesive. Generally, the external cross-linker is blended in an amount of preferably about 5 parts by weight or less, further preferably 0.1 to 5 parts by weight, based on 100 parts by weight of the base polymer. Further, for the pressure-sensitive adhesive, various kinds of previously known additives, such as a tackifier and an anti-aging agent, may be used as necessary in addition to the aforementioned components.

The pressure-sensitive adhesive layer 1b can be formed by a radiation curing-type pressure-sensitive adhesive. By irradiating the radiation curing-type pressure-sensitive adhesive with radiations such as ultraviolet rays, the degree of cross-linking thereof can be increased to easily reduce its adhesive power, so that pickup can be easily performed. Examples of radiations include X-rays, ultraviolet rays, electron rays, α rays, β rays, and neutron rays.

For the radiation curing-type pressure-sensitive adhesive, one having a radiation-curable functional group such as a carbon-carbon double bond and showing adherability can be used without particular limitation. Examples of the radiation curing-type pressure-sensitive adhesive may include, for example, an addition-type radiation-curable pressure-sensitive adhesive obtained by blending a radiation-curable monomer component or an oligomer component with a general pressure-sensitive adhesive such as the above-mentioned acryl-based pressure-sensitive adhesive or rubber-based pressure-sensitive adhesive.

Examples of the radiation curable monomer component to be blended include urethane oligomer, urethane (meth)acrylate, trimethylolpropane tri(meth)acrylate, tetramethylolmethane tetra(meth)acrylate, pentaerythrithol tri(meth)acrylate, pentaerythrithol tetra(meth)acrylate, dipentaerythrithol monohydroxypenta(meth)acrylate, dipentaerythrithol hexa(meth)acrylate, and 1,4-butanediol di(meth)acrylate. Examples of the radiation curable oligomer component include various oligomers such as urethane-based, polyether-based, polyester-based, polycarbonate-based and polybutadiene-based oligomers, and the appropriate weight-average molecular weight thereof is in a range of about 100 to 30,000. For the blending amount of the radiation curable monomer component or oligomer component, an amount allowing the adhesive strength of the pressure-sensitive adhesive layer to be reduced can be appropriately determined according to the type of the pressure-sensitive adhesive layer. Generally, the blending amount is, for example, 5 to 500 parts by weight, preferably about 40 to 150 parts by weight, based on 100 parts by weight of a base polymer such as an acryl-based polymer forming the pressure-sensitive adhesive.

Examples of the radiation curing-type pressure-sensitive adhesive include, besides the addition-type radiation curing-type pressure-sensitive adhesive described previously, an intrinsic radiation curing-type pressure-sensitive adhesive using, as a base polymer, a polymer having a carbon-carbon double bond in the polymer side chain or main chain or at the end of the main chain. The intrinsic radiation curing-type pressure-sensitive adhesive is preferable because it is not required to contain, or mostly does not contain an oligomer component or the like which is a low-molecular component, and therefore the oligomer component or the like does not migrate in the pressure-sensitive adhesive over time, so that a pressure-sensitive adhesive layer having a stable layer structure can be formed.

For the base polymer having a carbon-carbon double bond, one having a carbon-carbon double bond and also an adherability can be used without any particular limitation. Such a base polymer preferably has an acryl-based polymer as a basic backbone. Examples of the basic backbone of the acryl-based polymer include the acryl-based polymers described previously as an example.

The method for introducing a carbon-carbon double bond into the acryl-based polymer is not particularly limited, and various methods can be employed, but in molecular design it is easy to introduce the carbon-carbon double bond into a polymer side chain. For example, a method is mentioned in which a monomer having a functional group is copolymerized into an acryl-based polymer beforehand, and thereafter a compound having a functional group that can react with the above-mentioned functional group, and a carbon-carbon double bond is subjected to a condensation or addition reaction while maintaining the radiation curability of the carbon-carbon double bond.

Examples of the combination of these functional groups include a combination of a carboxylic acid group and an epoxy group, a combination of a carboxylic acid group and an aziridyl group, and a combination of a hydroxyl group and an isocyanate group. Among these combinations of functional groups, the combination of a hydroxyl group and an isocyanate group is suitable in terms of ease of reaction tracing. The functional group may be present at the side of any of the acryl-based polymer and the aforementioned compound as long as the combination of the functional groups is such a combination that the acryl-based polymer having a carbon-carbon double bond is generated, but for the preferable combination, it is preferred that the acryl-based polymer have a hydroxyl group and the aforementioned compound have an isocyanate group. In this case, examples of the isocyanate compound having a carbon-carbon double bond include metacryloyl isocyanate, 2-metacryloyloxyethyl isocyanate, m-isopropenyl-α,α-dimethylbenzyl isocyanate. As the acryl-based polymer, one obtained by copolymerizing the hydroxy group-containing monomers described previously as an example, ether-based compounds such as 2-hydroxyethylvinyl ether, 4-hydroxybutyl vinyl ether and diethylene glycol monovinyl ether, and so on is used.

For the intrinsic radiation curing-type pressure-sensitive adhesive, the base polymer (particularly acryl-based polymer) having a carbon-carbon double bond can be used alone, but the radiation curable monomer component or oligomer component within the bounds of not deteriorating properties can also be blended. The amount of the radiation curable oligomer component or the like is normally within a range of 30 parts by weight or less, preferably in a range of 0 to 10 parts by weight, based on 100 parts by weight of the base polymer.

A photopolymerization initiator is preferably included in the radiation curing-type pressure-sensitive adhesive when it is cured by ultraviolet rays or the like. Examples of the photopolymerization initiator include α-ketol-based compounds such as 4-(2-hydroxyethoxyl)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone-based compounds such as methoxyacetophenone, 2,2-dimethoxy-2-phenylacetophenone, 2,2-diethoxyacetophenone, and 2-methyl-1-[4-(methylthio)-phenyl]-2-morphorinopropane-1; benzoin ether-based compounds such as benzoin ethyl ether, benzoin isopropyl ether, and anisoin methyl ether; ketal-based compounds such as benzyldimethylketal; aromatic sulfonyl chloride-based compounds such as 2-naphthalenesulfonyl chloride; photoactive oxime-based compounds such as 1-phenone-1,1-propanedione-2-(o-ethoxycarbonyl)oxime; benzophenone-based compounds such as benzophenone, benzoyl benzoic acid, and 3,3′-dimethyl-4-methoxybenzophenone; thioxanthone-based compounds such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketone; acylphosphinoxide; and acylphosphonate. The blending amount of the photopolymerization initiator is, for example, about 0.05 to 20 parts by weight based on 100 parts by weight of the base polymer such as an acryl-based polymer which forms a pressure-sensitive adhesive.

When curing hindrance due to oxygen occurs at the time of irradiation, it is desirable to block oxygen (air) from the surface of the radiation curing-type pressure-sensitive adhesive layer 1b by some method. Examples include a method in which the surface of the pressure-sensitive adhesive layer 1b is covered with a separator, and a method in which irradiation of ultraviolet rays or the like is carried out in a nitrogen gas atmosphere.

The pressure-sensitive adhesive layer 1b may contain various kinds of additives (e.g. colorant, thickener, bulking agent, filler, tackifier, plasticizer, antiaging agent, antioxidant, surfactant, cross-linker, etc.).

The thickness of the pressure-sensitive adhesive layer 1b is not particularly limited, but is preferably about 1 to 50 μm from the viewpoint of compatibility of prevention of chipping of a chip cut surface, fixation and retention of the underfill sheet 2, and so on. The thickness is preferably 2 to 30 μm, more preferably 5 to

(Method for Manufacturing Underfill Sheet Integrated with Tape for Grinding Rear Surface)

For example, the tape 1 for grinding the rear surface and the underfill sheet 2 are separately produced and they are finally pasted to each other to make the underfill sheet integrated with a tape for grinding the rear surface 10.

(Method for Manufacturing Semiconductor Device Using Underfill Sheet Integrated with Tape for Grinding Rear Surface)

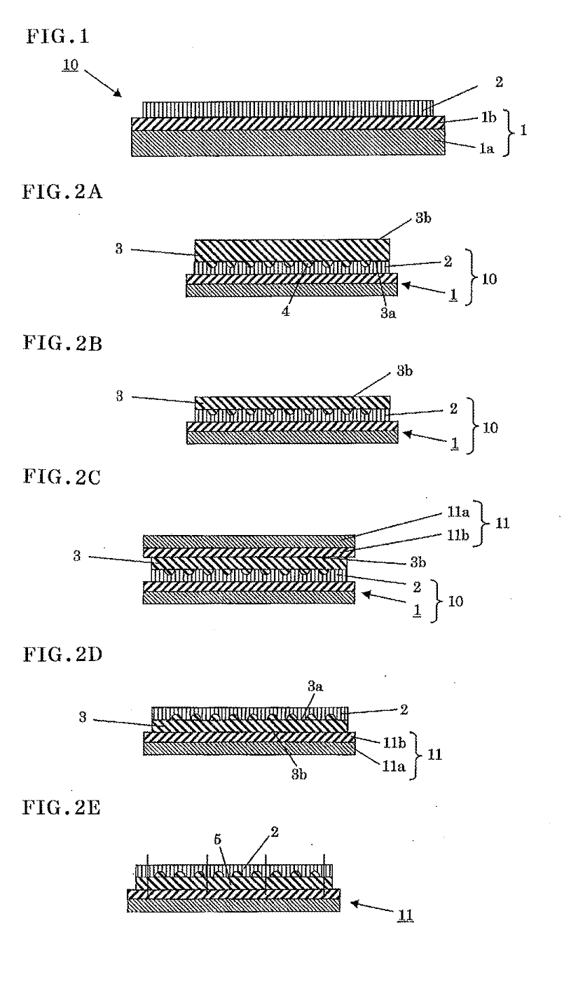

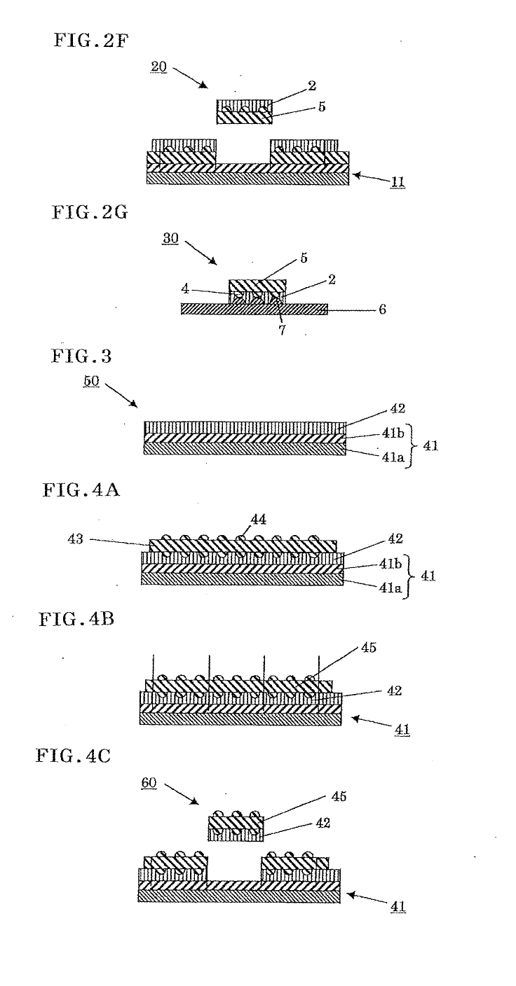

Next, a method for manufacturing a semiconductor device using the underfill sheet integrated with a tape for grinding the rear surface 10 will be described. Each of FIGS. 2A to 2G is a view showing each step of the method for manufacturing a semiconductor device using the underfill sheet integrated with a tape for grinding the rear surface 10.

Specifically, the method for manufacturing a semiconductor device includes: a pasting step of pasting, to the underfill sheet 2 of the underfill sheet integrated with a tape for grinding the rear surface 10, a circuit surface 3a on which connection members 4 of the semiconductor wafer 3 are formed; a grinding step of grinding a rear surface 3b of the semiconductor wafer 3; a wafer fixing step of pasting a dicing tape 11 to the rear surface 3b of the semiconductor wafer 3; a peeling step of peeling the tape 1 for grinding the rear surface; a dicing step of dicing the semiconductor wafer 3 to form a semiconductor chip 5 with the underfill sheet 2; a pickup step of peeling the semiconductor chip 5 with the underfill sheet 2 from the dicing tape 11; a connecting step of electrically connecting the semiconductor chip 5 and an adherend 6 through the connection member 4 while filling the space between the semiconductor chip 5 and the adherend 6 with the underfill sheet 2; and a curing step of curing the underfill sheet 2.

<Fasting Step>

In the pasting step, the circuit surface 3a on which the connection members 4 of the semiconductor wafer 3 are formed is pasted to the underfill sheet 2 of the underfill sheet integrated with a tape for grinding the rear surface 10 (refer to FIG. 2A).

A plurality of the connection members 4 are formed on the circuit surface 3a of the semiconductor wafer 3 (refer to FIG. 2A). The material of the connection member 4 is not especially limited, and examples of the material include solders (alloys) such as tin-lead metal, tin-silver metal, tin-silver-copper metal, tin-zinc metal, and tin-zinc-bismuth metal; gold metal; and copper metal. The height of the connection member 4 is determined depending on its use, and it is generally about 15 to 100 μm. Naturally, the height of each connection member 4 in the semiconductor wafer 3 may be the same or different from each other.

A height X (μm) of the connection member 4 that is formed on the semiconductor wafer 3 surface and a thickness Y (μm) of the underfill sheet 2 preferably satisfy the following relationship:

0.5≦Y/X≦2.

When the height X (μm) of the connection member 4 and the thickness Y (μm) of the underfill sheet 2 satisfy the above relationship, the space between the semiconductor chip 5 and the adherend 6 can be sufficiently filled, excess protrusion of the underfill sheet 2 from the space can be prevented, and contamination, etc. of the semiconductor chip 5 by the underfill sheet 2 can be prevented. When the height of each connection member 4 is different from each other, the largest height of the connection member 4 is set as a standard.

First, a separator that is arbitrarily provided on the underfill sheet 2 of the underfill sheet integrated with a tape for grinding the rear surface 10 is appropriately peeled, and the circuit surface 3a on which the connection members 4 of the semiconductor wafer 3 are formed is arranged to face the underfill sheet 2 as shown in FIG. 2A, so that the underfill sheet 2 and the semiconductor wafer 3 are pasted together (mounting).

The method of the pasting is not especially limited; however, a method of press-bonding is preferable. The pressure of press-bonding is preferably 0.1 MPa or more, and more preferably 0.2 MPa or more. If the pressure is 0.1 MPa or more, the unevenness of the circuit surface 3a of the semiconductor wafer 3 can be suitably filled. The upper limit of the pressure of press-bonding is not especially limited; however, it is preferably 1 MPa or less, and more preferably 0.5 MPa or less.

The temperature at the pasting is preferably 60° C. or higher, and more preferably 70° C. or higher. If the temperature is 60° C. or higher, the viscosity of the underfill sheet 2 decreases, and the underfill sheet 2 can fill the unevenness of the semiconductor wafer 3 without any gaps. The temperature at the pasting is preferably 100° C. or lower, and more preferably 80° C. or lower. If the temperature is 100° C. or lower, the pasting can be performed while suppressing the curing reaction of the underfill sheet 2.

The pasting is preferably performed under reduced pressure, for example, 1,000 Pa or less, and preferably 500 Pa or less. The lower limit is not especially limited, and is, for example, 1 Pa or more.

<Grinding Step>

In the grinding step, the surface opposite to the circuit surface 3a of the semiconductor wafer 3 (that is, rear surface 3b) is ground (refer to FIG. 2B). A thin-type processing machine that is used in grinding the rear surface of the semiconductor wafer 3 is not especially limited, and examples thereof include a grinding machine (back grinder) and a polishing pad. The rear surface may be grinded with a chemical method such as etching. The rear surface is grinded until the thickness of the semiconductor wafer 3 reaches a desired thickness (for example, 700 to 25 μm).

<Wafer Fixing Step>

After the grinding step, the dicing tape 11 is pasted to the rear surface 3b of the semiconductor wafer 3 (refer to FIG. 2C). The dicing tape 11 has a structure in which a pressure-sensitive adhesive layer 11b is laminated on a base 11a. The base 11a and the pressure-sensitive adhesive layer 11b can be suitably produced using the components and the manufacture method shown in the section of the base 1a and pressure-sensitive adhesive layer 1b of the tape 1 for grinding the rear surface.

<Peeling Step>

Next, the tape 1 for grinding the rear surface is peeled (refer to FIG. 2D). This allows the underfill sheet 2 to be exposed.

When the pressure-sensitive adhesive layer 1b is radiation curable, the pressure-sensitive adhesive layer 1b is cured by irradiating the layer 1b with radiation to easily peel the tape 1 for grinding the rear surface. The amount of radiation may be appropriately set in consideration of the type of radiation to be used, the degree of curing of the pressure-sensitive adhesive layer, etc.

<Dicing Step>

In the dicing step, the semiconductor wafer 3 and the underfill sheet 2 are diced to form the semiconductor chip 5 with the underfill sheet 2 as shown in FIG. 2E. The dicing is performed from the circuit surface 3a to which the underfill sheet 2 of the semiconductor wafer 3 is pasted with a normal method. An example includes a cutting method called full cut in which cutting is performed up to the dicing tape 11. The dicing apparatus that is used in this step is not especially limited, and a conventionally known apparatus can be used.

When the expansion of the dicing tape 11 is performed successively after the dicing step, the expansion can be performed by using a conventionally known expanding apparatus.

<Pickup Step>

In order to collect the semiconductor chip 5 that is attached and fixed to the dicing tape 11, pickup of the semiconductor chip 5 with the underfill sheet 2 is performed to peel a laminate 20 off the semiconductor chip 5 and the underfill sheet 2 from the dicing tape 11 as shown in FIG. 2F.

The pickup method is not especially limited, and various types of conventionally known methods can be adopted.

When the pressure-sensitive adhesive layer 11b of the dicing tape 11 is ultraviolet curable, the pickup is performed after irradiating the pressure-sensitive adhesive layer 11b with ultraviolet rays. This allows the adhesive strength of the pressure-sensitive adhesive layer 11b to the semiconductor wafer 5 to be decreased, and makes peeling of the semiconductor chip 5 easy.

As a result, the pickup can be performed without damaging the semiconductor chip 5.

<Connecting Step>

In the connecting step, the semiconductor chip 5 and the adherend 6 are electrically connected to each other through the connection member 4 while filling the space between the adherend 6 and the semiconductor chip 5 with the underfill sheet 2 (refer to FIG. 2G). Specifically, the semiconductor chip 5 of the laminate 20 is fixed to the adherend 6 with a normal method such that the circuit surface 3a of the semiconductor chip 5 faces the adherend 6. For example, the connection member 4 that is formed on the semiconductor chip 5 is brought into contact with a conductive material 7 for bonding that is attached to the connection pad of the adherend 6, and the conductive material 7 is melted while pressing the connection member 4 to secure electrical connection between the semiconductor chip 5 and the adherend 6 so that the semiconductor chip 5 can be fixed to the adherend 6. Since the underfill sheet 2 is pasted to the circuit surface 3a of the semiconductor chip 5, the semiconductor chip 5 and the adherend 6 are electrically connected to each other and the space between the semiconductor chip 5 and the adherend 6 is filled with the underfill sheet 2.

The heating condition in the connecting step is the same as the heating condition of the underfill sheet.

The underfill sheet 2 has the above-described viscosity characteristics, so that the fluidity falls within the optimum range under the heating condition, the underfill sheet can suitably fill the unevenness of the semiconductor element surface, and the terminals can be suitably connected to each other. The generation of voids due to outgas can be suppressed. Under the heating condition, one or both of the connection member 4 and the conductive material 7 can be melted.

The heat press-bonding process in the connecting step may be performed in multiple stages. When the heat press-bonding process is performed in multiple stages, the resin between the connection member and the pad can be effectively removed, and better connection between metals can be obtained.

The pressure application condition is not especially limited, and it is preferably 10 N or more, and more preferably 20 N or more. If the pressure application is 10 N or more, the underfill located between the connection terminal and the connection substrate can be easily pushed away, and a better connection can be easily obtained. The upper limit is preferably 300 N or less, and more preferably 150 N or less. If the pressure application is 300 N or less, damage to the semiconductor chip 5 can be suppressed.

<Curing Step>

After the semiconductor element 5 and the adherend 6 are electrically connected to each other, the underfill sheet 2 is cured by heating. This makes it possible to protect the surface of the semiconductor element 5, and to secure the connection reliability between the semiconductor element 5 and the adherend 6. The heating temperature for curing the underfill sheet 2 is not especially limited, and for example, is 150 to 200° C. for 10 to 120 minutes. The underfill sheet may be cured by the heating process in the connecting step.

<Sealing Step>

Next, a sealing step may be performed for protecting an entire semiconductor device 30 including the mounted semiconductor chip 5. The sealing step is performed by using a sealing resin. The sealing condition is not especially limited, and heating is normally performed at 175° C. for 60 to 90 seconds to thermally cure the sealing resin. However, the present invention is not limited to this. For example, the curing can be performed at 165 to 185° C. for a few minutes.

A resin having an insulating property (an insulating resin) is preferable as the sealing resin, and the sealing resin can be appropriately selected from sealing resins known for use.

<Semiconductor Device>

In the semiconductor device 30, the semiconductor chip 5 and the adherend 6 are electrically connected to each other through the connection member 4 that is formed on the semiconductor chip 5 and the conductive material 7 that is provided on the adherend 6. The underfill sheet 2 is arranged between the semiconductor element 5 and the adherend 6 so that it fills the space.

[Underfill Sheet Integrated with Dicing Tape]

The underfill sheet integrated with a dicing tape of the present invention includes a dicing tape and the underfill sheet.

FIG. 3 is a schematic cross sectional view of an underfill sheet integrated with a dicing tape 50. As shown in FIG. 3, the underfill sheet integrated with a dicing tape 50 includes a dicing tape 41 and an underfill sheet 42 that is laminated on the dicing tape 41.

The dicing tape 41 includes a base 41a and a pressure-sensitive adhesive layer 41b that is laminated on the base 41a. Those provided as examples for the base 1a can be used as the base 41a. Those provided as examples for the pressure-sensitive adhesive layer 1b can be used as the pressure-sensitive adhesive layer 41b.

(Method for Manufacturing Semiconductor Device Using Underfill Sheet Integrated with Dicing Tape)

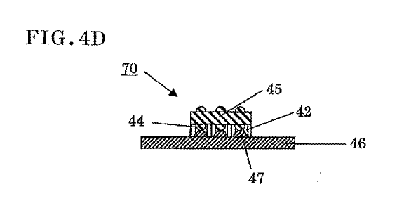

Next, a method for manufacturing a semiconductor device using the underfill sheet integrated with a dicing tape 50 will be explained. Each of FIGS. 4A to 4D is a view showing each step of the method for manufacturing a semiconductor device using the underfill sheet integrated with a dicing tape 50. Specifically, the method for manufacturing a semiconductor device includes: a pasting step of pasting to the underfill sheet 42 of the underfill sheet integrated with a dicing tape 50, a semiconductor wafer 43, both surfaces of which are formed with circuit surfaces having connection members 44; a dicing step of dicing the semiconductor wafer 43 to form a semiconductor chip 45 with the underfill sheet 42; a pickup step of peeling the semiconductor chip 45 with the underfill sheet 42 from the dicing tape 41; a connecting step of electrically connecting the semiconductor chip 45 and an adherend 46 through the connection member 44 while filling the space between the semiconductor chip 5 and the adherend 6 with the underfill sheet 42; and a curing step of curing the underfill sheet 42.

<Pasting Step>

In the pasting step, the semiconductor wafer 43, both surfaces of which are formed with circuit surfaces having connection members 44, is pasted to the underfill sheet 42 of the underfill sheet integrated with a dicing tape 50 as shown in FIG. 4A. The semiconductor wafer 43 is normally weak in strength, so that the semiconductor wafer may be fixed to a support such as a support glass for reinforcement (not shown). In this case, a step of peeling the support may be included after pasting the semiconductor wafer 43 to the underfill sheet 42. Which circuit surface of the semiconductor wafer 43 is pasted to the underfill sheet 42 may be changed depending on the structure of a desired semiconductor device.

The connection members 44 on both surfaces of the semiconductor wafer 43 may be or may not be electrically connected to each other. An example of the electric connection of the connection members 44 includes a connection through a via, which is called a through silicon via (TSV). The pasting condition described in the step of pasting the underfill sheet integrated with a tape for grinding the rear surface can be adopted as the pasting condition.

<Dicing Step>

In the dicing step, the semiconductor wafer 43 and the underfill sheet 42 are diced to form the semiconductor chip 45 with the underfill sheet 42 (refer to FIG. 4B).

The dicing condition described in the step of dicing the underfill sheet integrated with a tape for grinding the rear surface can be adopted as the dicing condition.

<Pickup Step>

In the pickup step, the semiconductor chip 45 with the underfill sheet 42 is peeled from the dicing tape 41 (FIG. 4C).

The pickup condition described in the step of picking up the underfill sheet integrated with a tape for grinding the rear surface can be adopted as the pickup condition.

<Connecting Step>

In the connecting step, the semiconductor element 45 and the adherend 46 are electrically connected to each other through the connection member 44 while filling the space between the semiconductor chip 45 and the adherend 46 with the underfill sheet 42 (refer to Fig. D). A specific connection method is the same as the contents described in the connecting step of the underfill sheet integrated with a tape for grinding the rear surface. The heating condition in the connecting step is the same as the heating condition of the underfill sheet described above.

<Curing Step and Sealing Step>

The curing step and the sealing step are the same as the contents described in the curing step and the sealing step of the underfill sheet integrated with a tape for grinding the rear surface. This makes it possible to manufacture a semiconductor device 70.

### Examples

The preferred working examples of this invention will be explained in detail below. However, the materials, the compounding amounts, etc., described in the working examples are not intended to be limited thereto in the scope of this invention unless otherwise specified. The “part(s)” in the working examples means “part(s) by weight”.

[Production of Underfill Sheet]

The following components were dissolved in methylethylketone at the proportions shown in Table 1 to prepare solutions of adhesive compositions, each of which has a solid concentration of 23.6 to 60.6% by weight.

Acrylic resin 1: Acrylic acid ester polymer containing butylacrylate-acrylonitrile as amain component (trade name “SG-28GM” manufactured by Nagase ChemteX Corporation)

Acrylic resin 2: Acrylic ester polymer containing ethylacrylate-methylmethacrylate as a main component (trade name “Paracron W-197CM” manufactured by Negami Chemical Industrial Co., Ltd.)

Epoxy resin 1: trade name “Epikote 828” manufactured by JSR Corporation

Epoxy resin 2: trade name “Epikote 1004” manufactured by JSR Corporation

Phenol resin: trade name “Milex XLC-4L” manufactured by Mitsui Chemicals, Inc.

Silica filler 1: Spherical silica (trade name “SO-25R” manufactured by Admatechs, average particle size: 500 nm (0.5 μm))

Silica filler 2: Spherical silica (trade name “YCO50C-MJF” manufactured by Admatechs, average particle size: 50 nm (0.05 μm))

Organic acid: O-anisic acid (trade name “Ortho-Anisic Acid” manufactured by Tokyo Chemical Industry Co., Ltd.)

Curing agent: Imidazole catalyst (trade name “2PHZ-PW” manufactured by Shikoku Chemicals Corporation)

Each of the solutions of the adhesive compositions was applied onto a release-treated film of a silicone release-treated polyethylene terephthalate film having a thickness of 50 μm as a release liner (separator), and the resultant was dried at 130° C. for 2 minutes to produce an underfill sheet having a thickness of 50 μm.

The following evaluations were performed on the obtained underfill sheet. The results are shown in Table 1.

(Measurement of Viscosity at 150° C. and 0.05 to 0.20 Rotations/Min)

A rheometer was used, and the gap was set to 100 μm. The measurement was performed for 300 seconds at a rotation speed of 0.1 rotations per minute while keeping the temperature at 150° C. The value that was measured after 300 seconds from the start of the measurement was considered to be the viscosity at 150° C.

(Measurement of Minimum Viscosity at 100 to 200° C. and 0.3 to 0.7 Rotations/Min)

A rheometer was used, the gap was set to 100 μm, and the rotation speed was set to 0.5 rotations per minute. The temperature was increased at a rising temperature speed of 10° C./min, the viscosity was increased by the curing reaction, and the measurement was performed until no rotation was obtainable. The minimum value of the viscosity from 100 to 200° C. was considered to be the minimum viscosity.

(Measurement of Thermal Expansion Coefficient α)

The thermal expansion coefficient α was measured using a thermomechanical measurement apparatus (model Q-400EM manufactured by TA Instruments). Specifically, a measurement sample 15 mm long×5 mm wide×200 μm thick was set to a tool for film tensile measurement on the apparatus. Then, the measurement sample was placed under conditions of a tensile load of 2 g and a rising temperature speed of 10° C./min in the temperature range of −50 to 300° C. The thermal expansion coefficient α was calculated from the expansion rate at 20 to 60° C.

(Measurement of Storage Modulus E′)

A thermal curing treatment was performed on the underfill sheet at 175° C. for 1 hour to measure the storage modulus by using a solid viscoelastic measurement apparatus (model: RSA-III manufactured by Rheometric Scientific, Inc.). That is, a sample 40 mm long×10 mm wide×200 μm thick was set to a tool for film tensile measurement, and the tensile storage modulus and the loss modulus in the temperature range of −50 to 300° C. were measured under conditions of a frequency of 1 Hz and a rising temperature speed of 10° C./min, so that the storage modulus (E′) at 25° C. was obtained.

(Measurement of Glass Transition Temperature)

First, the underfill sheet was thermally cured by heating treatment at 175° C. for 1 hour. Thereafter, the underfill sheet was cut into a rectangular shape of 200 μm in thickness, 40 mm in length (measurement length) and 10 mm in width, and the storage modulus and the loss modulus at −50 to 300° C. were measured by using a solid viscoelasticity measurement apparatus (RSA-III manufactured by Rheometric Scientific, Inc.). The measurement conditions were as follows: a frequency of 1 Hz and a rising temperature speed of 10° C./min. A value of tan δ (G″ (loss modulus)/G′ (storage modulus)) was calculated to obtain a glass transition temperature.

[Production of Underfill Sheet Integrated with Tape for Grinding Rear Surface]

The underfill sheet was pasted on the pressure-sensitive adhesive layer of a tape for grinding the rear surface (trade name “UB-2154” manufactured by Nitto Denko Corporation) using a hand roller to produce an underfill sheet integrated with a tape for grinding the rear surface.

[Production of Semiconductor Device]

A silicon wafer with one-side bump was prepared in which bumps were formed on one side of the wafer. The produced underfill sheet integrated with a tape for grinding the rear surface was pasted to the surface of the silicon wafer with one-side bump where the bumps were formed by using the underfill sheet as the pasting surface. The following silicon wafer was used as the silicon wafer with one-side bump. The pasting conditions are as follows. The ratio (Y/X) of the thickness Y (=45 μm) of the underfill sheet to the height X (=45 μm) of the bump was 1.

<Silicon Wafer with One-Side Bump>

Diameter of silicon wafer: 8 inches

Thickness of silicon wafer: 0.7 mm (700 μm)

Height of bump: 45 μm

Pitch of bump: 50 μm

Material of bump: tin-silver eutectic solder

<Pasting Conditions>

Pasting apparatus: trade name “DSA840-WS” manufactured by Nitto Seiki Co., Ltd.

Pasting speed: 5 mm/min

Pasting pressure: 0.25 MPa

Stage temperature at pasting: 70° C.

Degree of reduced pressure at pasting: 150 Pa

After pasting, the rear surface of the silicon wafer was grinded. After grinding, the silicon wafer was peeled from the tape for grinding the rear surface together with the underfill sheet, and the silicon wafer was pasted to a dicing tape to perform dicing of the silicon wafer. The dicing was performed in full cut so that the chip size became a 7.3 mm square. Next, the laminate of the underfill sheet and the silicon chip with one-side bump was picked up with a pushing-up method by a needle from the base side of each dicing tape. The pickup conditions are as follows.

<Pickup Conditions>

Pickup apparatus: trade name “SPA-300” manufactured by Shinkawa Ltd.

Number of needles: 9 needles

Needle pushing-up amount: 500 μm (0.5 mm)

Needle pushing-up speed: 20 mm/sec

Pickup time: 1 second

Expanding amount: 3 mm

Finally, mounting of the silicon chip was performed by thermally press-bonding the silicon chip to a BGA substrate with the bump formation surface of the silicon chip facing to the BGA substrate under thermal press-bonding conditions described below. This provided a semiconductor device in which the silicon chip was mounted to the BGA substrate.

<Thermal Press-Bonding Conditions>

Thermal press-bonding apparatus: trade name “FCB-3” manufactured by Panasonic Corporation

Heating temperature: 260° C.

Load: 30 N

Holding time: 10 seconds

The following evaluations were performed on the obtained semiconductor device. The results are shown in Table 1.

(Evaluation of Voids)

The obtained semiconductor device was polished to the underfill resin portion in parallel with the chip side, and the underfill was observed under a microscope to check for the presence or absence of voids. The case of the absence of voids was determined as ◯, and the case of the presence of voids was determined as x.

(Evaluation of Connection Between Terminals)

The semiconductor device was polished in the vertical direction so that the solder bonding portion was exposed. The case in which the polished cross section was not broken was determined as ◯ (a good product), and the case in which the polished cross section was broken was determined as x (a defective product).

(Evaluation of Reliability)

Ten samples of the semiconductor device were made, and a heat cycle cycling once from −55 to 125° C. in 30 minutes was repeated 500 times. Then, the semiconductor device was embedded in the epoxy resin for embedding. Next, the semiconductor device was cut in a direction perpendicular to the substrate so that the solder bonding portion was exposed, and the exposed cross section of the solder bonding portion was polished. Thereafter, the polished cross section of the solder bonding portion was observed under an optical microscope (magnification: 1,000×). The case in which the solder bonding portion was not broken was evaluated as a good product, and the case in which the solder bonding portion was broken was evaluated as a defective product.

TABLE 1

| | | | | | | | Compar- | Compar- | Compar- | Compar- |
|---|---|---|---|---|---|---|---|---|---|---|
| | | Exam- | Exam- | Exam- | Exam- | Exam- | ative | ative | ative | ative |
| | | ple 1 | ple 3 | ple 3 | ple 4 | ple 5 | Example 1 | Example 2 | Example 3 | Example 4 |
| Com- | Acrylic Resin 1 | — | — | 6 | — | — | — | — | 6 | 3 |
| pound- | Acrylic Resin 2 | 10 | 15 | — | 25 | 6 | 1 | 43 | — | — |
| ing | Epoxy Resin 1 | 10 | 10 | 15 | 5 | 5 | 15 | 10 | 10 | 20 |
| (parts | Epoxy Resin 2 | 10 | 10 | 5 | 15 | 15 | 5 | 10 | 10 | — |
| by | Phenol Resin | 23 | 23 | 23 | 23 | 23 | 23 | 23 | 23 | 23 |
| weight) | Silica Filler 1 | 67.5 | — | 97 | 48 | — | 48 | 48 | 5 | 150 |
| | Silica Filler 2 | — | 67.5 | — | — | 10 | — | — | — | — |
| | Organic Acid | 2.7 | 2.7 | 2.7 | 2.7 | 2.7 | 2.7 | 2.7 | 2.7 | 2.7 |
| | Curing Agent | 0.15 | 0.15 | 0.15 | 0.15 | 0.15 | 0.15 | 0.15 | 0.15 | 0.15 |
| Eval- | Viscosity [Pa · s] at 150° C. | 3600 | 5400 | 1500 | 7000 | 1700 | 600 | 15000 | 800 | 1200 |
| uation | and 0.05 to 0.20 rotations/min | | | | | | | | | |
| | Minimum Viscosity [Pa · s] | 300 | 460 | 130 | 2300 | 150 | 60 | 5000 | 40 | 90 |
| | at 100 to 200° C. and 0.3 | | | | | | | | | |
| | to 0.7 rotations/min | | | | | | | | | |
| | Thermal Expansion Coefficient | 48 | 60 | 18 | 110 | 78 | 16 | 112 | 79 | 15 |
| | α [ppm/K] | | | | | | | | | |
| | Storage Modulus E′ [MPa] | 2000 | 1800 | 6800 | 780 | 2400 | 6200 | 800 | 1700 | 7100 |
| | Tg [° C.] | 128 | 127 | 140 | 138 | 144 | 136 | 136 | 138 | 129 |
| | α × E′ [Pa/K] | 96000 | 108000 | 122400 | 85800 | 187200 | 99200 | 89600 | 134300 | 106500 |
| | Void | ∘ | ∘ | ∘ | ∘ | ∘ | x | ∘ | x | x |
| | Connection between Terminals | ∘ | ∘ | ∘ | ∘ | ∘ | ∘ | x | x | ∘ |
| | Reliability Test | 10/10 | 10/10 | 10/10 | 10/10 | 10/10 | 0/10 | 0/10 | 0/10 | 0/10 |
| | Number of Good Products | | | | | | | | | |

### DESCRIPTION OF REFERENCE CHARACTERS

1 Tape for Grinding Rear Surface
1a Base
1b Pressure-Sensitive Adhesive Layer
2 Underfill Sheet
3 Semiconductor Wafer
3a Circuit Surface of Semiconductor Wafer
3b Surface opposite to Circuit Surface of Semiconductor Wafer
4 Connection Member (Bump)
5 Semiconductor Chip
6 Adherend
7 Conductive Material
10 Underfill Sheet Integrated with Tape for Grinding Rear Surface
11 Dicing Tape
11a Base
11b Pressure-Sensitive Adhesive Layer
20 Laminate
30 Semiconductor Device
41 Dicing Tape
41a Base
41b Pressure-Sensitive Adhesive Layer
42 Underfill Sheet
43 Semiconductor Wafer
44 Connection Member (Bump)
45 Semiconductor Chip
46 Adherend
47 Conductive Material
50 Underfill Sheet Integrated with Dicing Tape
60 Laminate
70 Semiconductor Device

1. An underfill sheet having:
a viscosity of 1,000 Pa·s to 10,000 Pa·s at 150° C. and 0.05 to 0.20 rotations/min; and
a minimum viscosity of 100 Pa·s or more at 100 to 200° C. and 0.3 to 0.7 rotations/min.

2. The underfill sheet according to claim 1, comprising 15 to 70% by weight of a silica filler having an average particle size of 0.01 to 10 μm and 2 to 30% by weight of an acrylic resin.

3. The underfill sheet according to claim 1, wherein a storage modulus E′ [MPa] and a thermal expansion coefficient α [ppm/K] after thermally curing at 175° C. for 1 hour satisfy the following Formula (1) at 25° C.:
E′×α<250,000 [Pa/K] (1).

4. The underfill sheet according to claim 3, wherein the storage modulus E′ is 100 to 10,000 [MPa], and the thermal expansion coefficient α is 10 to 200 [ppm/K].

5. The underfill sheet according to claim 3, wherein the storage modulus E′ [MPa] and the thermal expansion coefficient α [ppm/K] satisfy the following Formula (2):
10,000<E′×α<250,000 [Pa/K] (2).

6. The underfill sheet according to claim 1, comprising a thermosetting resin.

7. The underfill sheet according to claim 6, wherein the thermosetting resin contains an epoxy resin and a phenol resin.

8. An underfill sheet integrated with a tape for grinding a rear surface, comprising the tape for grinding the rear surface and the underfill sheet according to claim 1 laminated on the tape for grinding the rear surface.

9. An underfill sheet integrated with a dicing tape, comprising a dicing tape and the underfill sheet according to claim 1 laminated on the dicing tape.

10. A method for manufacturing a semiconductor device, comprising a step of fixing a semiconductor element to an adherend with the underfill sheet according to claim 1 interposed therebetween.
